(19) United States
(12) Patent Application Publication
(10) Pub. No.: US 2016/0181983 A1
(43) Pub. Date: Jun. 23, 2016

(54) LOW POWER OPERATIONAL TRANSCONDUCTANCE AMPLIFIER

(71) Applicant: QUALCOMM Incorporated, San Diego, CA (US)

(72) Inventor: Ganesh Kiran, San Diego, CA (US)

(21) Appl. No.: 14/577,950

(22) Filed: Dec. 19, 2014

(51) Int. Cl. H03F 1/02; H03F 1/22; H03F 3/45

(52) U.S. Cl. CPC H03F 1/0205; H03F 3/45179; H03F 1/223; H03F 2203/45288

(57) ABSTRACT

A low power operational transconductance amplifier is disclosed. In an exemplary embodiment, an apparatus includes a transconductance stage configured to convert a first input voltage signal to first and second current signals and to convert a second input voltage signal to third and fourth current signals. The apparatus also includes a current amplification stage configured to amplify the second current signal to generate a first amplified current signal and to amplify the fourth current signal to generate a second amplified current signal. The apparatus also includes a current summation stage configured to sum together the third current signal and the first amplified current signal to generate a first output voltage signal, and to sum together the first current signal and the second amplified current signal to generate a second output voltage signal.

### BACKGROUND

I. Field

The present disclosure relates generally to electronics, and more specifically to low power amplifiers.

II. Background

A wireless device (e.g., a cellular phone or a smartphone) in a wireless communication system may transmit and receive data for two-way communication. For example, the wireless device may operate in a frequency division duplexing (FDD) system or in a time division duplexing system (TDD). The wireless device may include a transmitter for data transmission and a receiver for data reception. Thus, the wireless device may process both analog and digital signals in order to provide communication and/or data services.

Operational Transconductance Amplifiers (OTAs) are common components in many analog/mixed-signal systems. OTAs are used in mixed signal systems like Delta Sigma analog to digital converters (ADC) and Pipelined ADCs, which are popular ways to realize robust ADCs that are relatively immune to transistor parameter variations. Unfortunately, due to shrinking supply voltages in deep submicron technologies, it has become increasingly difficult to provide amplification with acceptable DC gain. While it is possible to use multi-stage architectures like Miller compensated amplifiers and feed forward amplifiers to get around this issue, they are either not very power efficient and/or do not possess good settling behavior important in many switched capacitor circuits and usually have a noise penalty. Furthermore, in systems like MASH delta sigma ADCs, DC gain and settling are the very important parameters that decide the overall ADC performance and a significant portion of the power budget is spent in achieving these.

It is therefore desirable to have a low power operational transconductance amplifier that overcomes the disadvantages of conventional circuits.

### BRIEF DESCRIPTION OF THE DRAWINGS

FIG. 1 shows an exemplary embodiment of an operational transconductance amplifier for use in a wireless device communicating within a wireless system.

FIG. 2 shows three exemplary band groups in which exemplary embodiments of the operational transconductance amplifier shown in FIG. 1 may operate.

FIG. 3 shows a switched capacitor filter that includes an exemplary embodiment of an operational transconductance amplifier.

FIG. 4 shows an exemplary embodiment of a functional block diagram of the operational transconductance amplifier shown in FIG. 3.

FIG. 5 shows a detailed exemplary embodiment of the operational transconductance amplifier shown in FIG. 4.

FIG. 6 shows exemplary operations performed by an exemplary embodiment of the operational transconductance amplifier.

FIG. 7 shows an exemplary embodiment of an operational transconductance amplifier apparatus.

### DETAILED DESCRIPTION

The detailed description set forth below is intended as a description of exemplary designs of the present disclosure and is not intended to represent the only designs in which the present disclosure can be practiced. The term “exemplary” is used herein to mean “serving as an example, instance, or illustration.” Any design described herein as “exemplary” is not necessarily to be construed as preferred or advantageous over other designs. The detailed description includes specific details for the purpose of providing a thorough understanding of the exemplary designs of the present disclosure. It will be apparent to those skilled in the art that the exemplary designs described herein may be practiced without these specific details. In some instances, well-known structures and devices are shown in block diagram form in order to avoid obscuring the novelty of the exemplary designs presented herein.

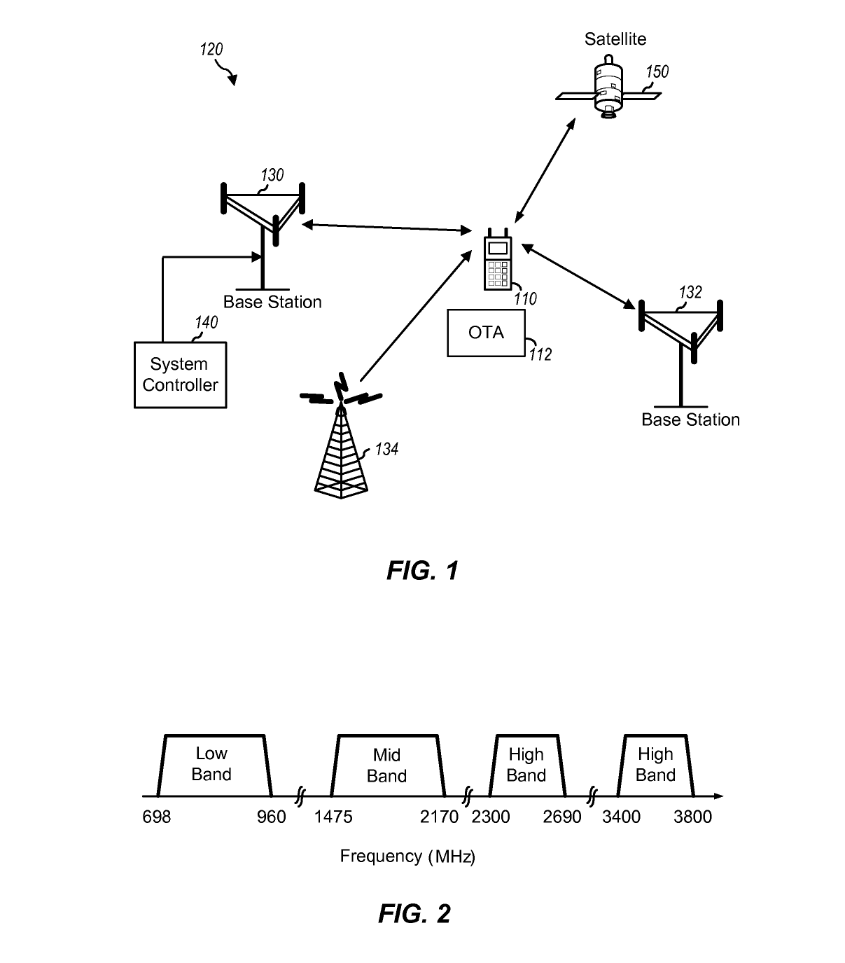

FIG. 1 shows an exemplary embodiment of an operational transconductance amplifier 112 for use in a wireless device 110 communicating within a wireless system 120. Wireless system 120 may be a Long Term Evolution (LTE) system, a Code Division Multiple Access (CDMA) system, a Global System for Mobile Communications (GSM) system, a wireless local area network (WLAN) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. For simplicity, FIG. 1 shows wireless system 120 including two base stations 130 and 132 and one system controller 140. In general, wireless system 120 may include any number of base stations and any set of network entities.

Wireless device 110 may also be referred to as a user equipment (UE), a mobile station, a terminal, an access terminal, a subscriber unit, or a station. Wireless device 110 may be a cellular phone, a smartphone, a tablet, a wireless modem, a personal digital assistant (PDA), a handheld device, a laptop computer, a smartbook, a netbook, a cordless phone, a wireless local loop (WLL) station, a Bluetooth device, or other communicating device. Wireless device 110 may communicate with devices in the wireless system 120. Wireless device 110 may also receive signals from broadcast stations (e.g., a broadcast station 134), or signals from satellites (e.g., a satellite 150) in one or more global navigation satellite systems (GNSS). Wireless device 110 may support one or more radio technologies for wireless communication such as LTE, WCDMA, CDMA 1X, EVDO, TD-SCDMA, GSM, 802.11. In an exemplary embodiment, the wireless device 110 comprises the operational transconductance amplifier 112 to provide amplification for use with various circuitries in the wireless device 110. For example, the operational transconductance amplifier may be used to provide amplification in switched capacitor circuits, analog to digital converters, and/or other circuitry within the wireless device 110. The OTA 112 is designed to utilize less power and provide improved DC gain and unity gain bandwidth over conventional amplifier circuits.

FIG. 2 shows three exemplary band groups in which exemplary embodiments of the wireless device 110 may operate. Wireless device 110 may operate in a low-band (LB) covering frequencies lower than 1000 megahertz (MHz), a mid-band (MB) covering frequencies from 1000 MHz to 2300 MHz, and/or a high-band (HB) covering frequencies higher than 2300 MHz. For example, the low-band may cover 698 to 960 MHz, the mid-band may cover 1475 to 2170 MHz, and the high-band may cover 2300 to 2690 MHz and 3400 to 3800 MHz, as shown in FIG. 2. The low-band, mid-band, and high-band refer to three groups of bands (or band groups), with each band group including a number of frequency bands (or simply, “bands”). Each band may cover up to 200 MHz. LTE Release 11 supports 35 bands, which are referred to as LTE/UMTS bands and are listed in 3GPP TS 36.101.

In general, any number of band groups may be defined. Each band group may cover any range of frequencies, which may or may not match any of the frequency ranges shown in FIG. 2. Each band group may also include any number of bands. In various exemplary embodiments, the OTA 112 is suitable for use within the various band groups to amplify signals within the wireless device 110.

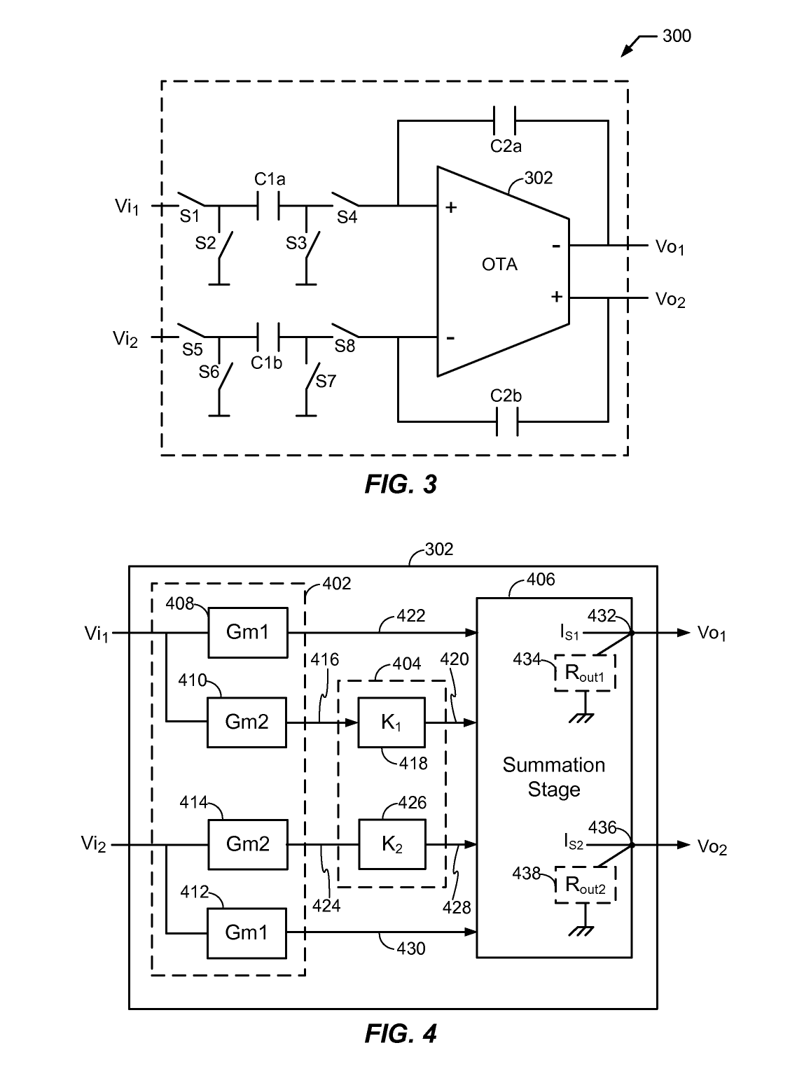

FIG. 3 shows a switched capacitor filter 300 that includes an exemplary embodiment of an operational transconductance amplifier 302. The filter 300 is suitable for use to filter signals in a wireless device, such as the device 110 shown in FIG. 1. Thus, the OTA 302 may be the OTA 112 shown in FIG. 1. The filter 300 includes eight switches (S1-S8) and capacitors C1a, C1b, C2a, and C2b that couple differential input signals Vi₁ and Vi₂ to non-inverting and inverting inputs of the OTA 302. The OTA 302 has differential output voltages Vol and Vo2 that are filtered versions of the input signals Vi₁ and Vi₂. For example, during operation, the switches S1-S8 are closed and opened at selected rates to move charges into and out of the capacitors C1a, C1b, C2a, and C2b. The filtering characteristics depend on the ratios between capacitances. The OTA 302 provides low power operation, and better DC gain and unity gain bandwidth over conventional amplifiers. The power savings provided by the exemplary embodiments of the OTA 302 can be significant since more than one OTA may be used in the wireless device 110.

FIG. 4 shows an exemplary embodiment of a functional block diagram of the operational transconductance amplifier 302 shown in FIG. 3. The OTA 302 includes a transconductance stage 402, a current amplification stage 404 and a current summation stage 406. The transconductance stage 402 comprises multiple transconductance (Gm) circuits where each Gm circuit generates an output current signal from an input voltage signal. For example, each transconductance circuit generates an output current that has a current level determined from the input voltage level multiplied by the transconductance value of the transconductance circuit (e.g., I=Vi*Gm).

The transconductance stage 402 includes transconductance circuit 408 that has a transconductance value of Gm1 and transconductance circuit 410 that has a transconductance value of Gm2. The transconductance circuits 408 and 410 receive the first differential input voltage Viᵢ and convert this voltage signal to generate a first current signal 422 and a second current signal 416. The first current signal 422 is input to the current summation stage 406 and the second current signal 416 is input to a first current amplifier 418 of the current amplification stage 404. The first current amplifier 418 amplifies (or multiplies) the second current signal 416 by a selected factor (K₁) to generate a first amplified (or multiplied) current signal 420 that is also input to the current summation stage 406. The factor (K₁) is typically a small integer value but may have any desired value.

The transconductance stage 402 also includes transconductance circuit 412 that has a transconductance value of Gm1 and transconductance circuit 414 that has a transconductance value of Gm2. The transconductance circuits 412 and 414 receive the second differential input voltage Vi₂ and convert this voltage signal to generate a third current signal 430 and a fourth current signal 424. The third current signal 430 is input to current summation stage 406 and the fourth current signal 424 is input to a second current amplifier 426 (or multiplier) of the current amplification stage 404. The current amplifier 426 amplifies (or multiplies) the fourth current signal 424 by a selected factor (K₂) to generate a second amplified (or multiplied) current signal 428 that is also input to the current summation stage 406. The factor (K₂) is typically a small integer value but may have any desired value. In an exemplary embodiment, the factors K₁ and K₂ are substantially the same value. In an exemplary embodiment, Gm1 is substantially the same value as Gm2; however, in other embodiments Gm1 and Gm2 have different values.

The current summation stage 406 sums together selected current signals that it receives at its inputs and generates a first summed current signal (I_{S1}) that is converted by a first impedance 434 at the terminal 432 to the first differential output voltage (V_{O1}) that appears at terminal 432. The current summation stage 406 also sums together selected current signals that it receives at its inputs and generates a second summed current signal (I_{S2}) that is converted by a second impedance 438 at the terminal 436 to the second differential output voltage signal (V_{O2}) that appears at the terminal 436.

Thus, the OTA 302 operates to convert input voltages to current signals, amplify and selectively sum the current signals to generate summed current signals that are converted to output voltages. The exemplary embodiments of the OTA consume significantly lower power compared to a conventional OTA, while achieving similar or better performance in terms of DC gain and unity gain bandwidth.

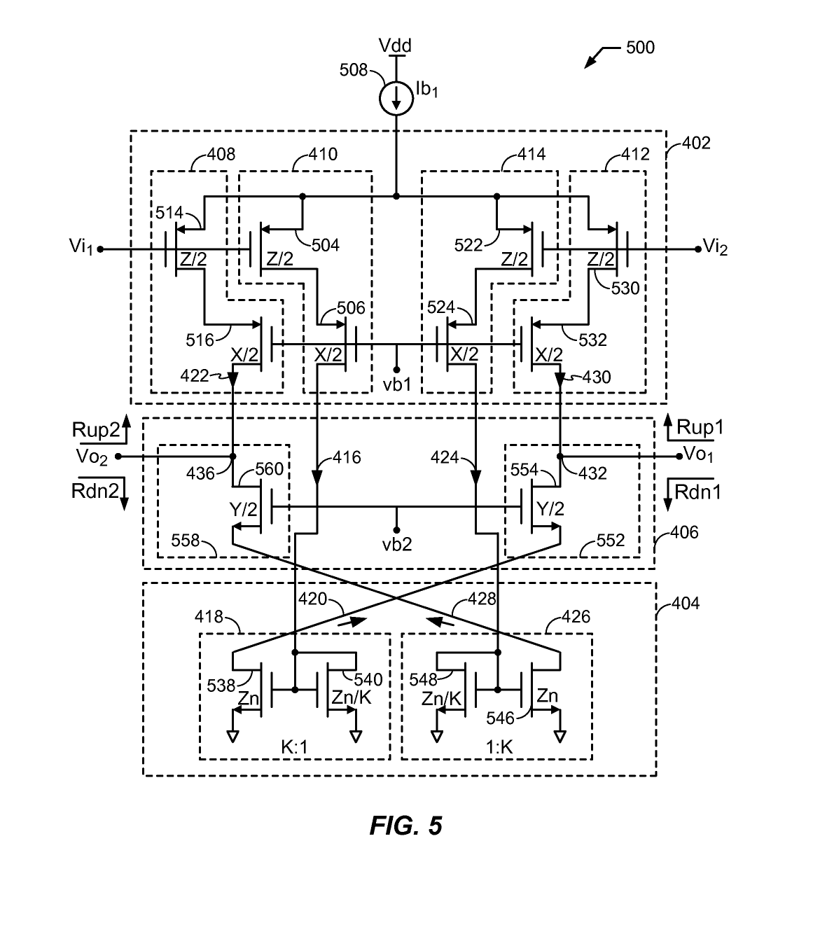

FIG. 5 shows a detailed exemplary embodiment of an operational transconductance amplifier 500. For example, the OTA 500 is suitable for use as the OTA 112 shown in FIG. 1 or the OTA 302 shown in FIG. 3 and FIG. 4. The OTA 500 comprises the transconductance stage 402, the amplification stage 404 and the summation stage 406 shown in FIG. 4. In this exemplary embodiment, the transconductance stage 402 comprises Gm circuits that are set such that (Gm1=Gm2) and the amplification factors are set such that (K₁=K₂=K). Thus, in the exemplary embodiment shown in FIG. 5, Gm1 is substantially equal to Gm2, and in other exemplary embodiments Gm1 may not be equal to Gm2.

The OTA 500 comprises the first Gm circuit 408 that includes transistors 514 and 516 in a cascode configuration. The transistor 514 has a source terminal connected to an output terminal of the current source 508 and a drain terminal connected to a source terminal of transistor 516. A drain terminal of the transistor 516 outputs the first current signal 422. A gate terminal of the transistor 514 is connected to receive the differential input voltage Vi1.

The OTA 500 comprises the second Gm circuit 410 that includes transistors 504 and 506 in a cascode configuration. The transistor 504 has a source terminal connected to the output terminal of the current source 508 and a drain terminal connected to a source terminal of the transistor 506. A drain terminal of the transistor 506 outputs the second current signal 416. A gate terminal of the transistor 504 is connected to receive the differential input voltage Vi1. A gate terminal of the transistor 506 is connected to a gate terminal of the transistor 516.

The OTA 500 comprises the third Gm circuit 412 that includes transistors 530 and 532 in a cascode configuration. The transistor 530 has a source terminal connected to the output terminal of the current source 508 and a drain terminal connected to a source terminal of the transistor 532. A drain terminal of the transistor 532 outputs the third current signal 430. A gate terminal of the transistor 530 is connected to receive the differential input voltage Vi2.

The OTA 500 comprises the fourth Gm circuit 414 that includes transistors 522 and 524 in a cascode configuration. The transistor 522 has a source terminal connected to the output terminal of the current source 508 and a drain terminal connected to a source terminal of the transistor 524. A drain terminal of the transistor 524 outputs the fourth current signal 424. A gate terminal of the transistor 522 is connected to receive the differential input voltage Vi2.

A gate terminal of the transistor 524 is connected to a gate terminal of the transistor 532. The gate terminal of the transistor 524 also is connected to the gate terminal of the transistor 506. In an exemplary embodiment, the Gm circuits 408, 410, 412 and 414 have transistors that are sized (e.g., channel lengths and widths) to provide the appropriate Gm values.

The gate terminals of transistors 516, 506, 524 and 532 are connected to receive a first voltage bias signal (vb1). The first voltage bias signal (vb1) is generated using a bias circuit or any suitable circuitry (not shown) that is known to those with skill in the art. The value of vb1 is chosen such that it is low enough to keep the transistors 514, 504, 522 and 530 in saturation. The value of vb1 is also chosen such that it is high enough so that the transistors 516, 506, 524 and 532 are in the saturation region during the highest voltage swings at the OTA outputs.

The first current amplifier 418 comprises common source transistors 538 and 540. The gate terminals of the transistors 538 and 540 are connected together and also connected to the drain terminal of the transistor 506 to receive the second current signal 416. The drain terminal of the transistor 540 is connected to its gate terminal and the drain terminal of the transistor 538 outputs the first amplified current 420. The first current amplifier 418 amplifies the first current signal 416 by a factor of (K) to generate the first amplified current signal 420.

The second current amplifier 426 comprises common source transistors 546 and 548. The gate terminals of the transistors 546 and 548 are connected together and also connected to the drain terminal of the transistor 524 to receive the fourth current signal 424. The drain terminal of the transistor 548 is connected to its gate terminal and the drain terminal of the transistor 546 outputs the second amplified current signal 428. The second current amplifier 426 amplifies the fourth current signal 424 by a factor of (K) to generate the second amplified current signal 428. It should be noted that the currents 422, 416, 424, 430, 420, and 428 are incremental small signal currents that flow through the circuit as indicated. These currents may not be the same as the DC current which flows generally from Vdd to the circuit (signal) ground.

The summation stage 406 includes a first summing circuit 552 and a second summing circuit 558. The first summing circuit 552 comprises transistor 554 that has a source terminal connected to the drain terminal of the transistor 538 to receive the first amplified current 420. The transistor 554 also has a drain terminal connected to the drain terminal of the transistor 532 at node 432 to receive the third current 430. The gate terminals of transistors 560 and 554 are connected to receive a second voltage bias signal (vb2). The second voltage bias signal (vb2) is generated using a bias circuit or any suitable circuitry (not shown) that is known to those with skill in the art. The value of vb2 is chosen such that it is high enough to keep the transistors 538, 540, 548 and 546 in saturation. The value of vb2 also is chosen to be low enough so that the transistors 560 and 554 are in the saturation region during the highest voltage swings at the OTA outputs.

The first summing circuit 552 sums the current 420 with the current 430 to generate a summed current that is converted to the differential output voltage Vo1 at the node 432 based on a first impedance that is formed by the output impedance (Rout1) looking into the node 432. For example, the output impedance (Rout1) looking into the node 432 is a parallel combination of the impedances Rup1 and Rdn1, so that the output impedance (Rout1) is determined from the expression [(Rup1×Rdn1)/(Rup1+Rdn1)].

The second summing circuit 558 comprises transistor 560 that has a source terminal connected to the drain terminal of the transistor 546 to receive the second amplified current 428. The transistor 560 also has a drain terminal connected to the drain terminal of the transistor 516 at node 436 to receive the first current 422. The transistor 560 has a gate terminal that is connected to a gate terminal of the transistor 554. The second summing circuit 558 sums the current 428 with the current 422 to generate a summed current that is converted to the second differential output voltage Vo2 at the node 436 based on a second impedance that is formed by the output impedance (Rout2) looking into the node 436. For example, the output impedance (Rout2) looking into the node 436 is a parallel combination of the impedances Rup2 and Rdn2, so that the output impedance (Rout2) is determined from the expression [(Rup2×Rdn2)/(Rup2+Rdn2)].

In various exemplary embodiments, the current amplification stage 404 increases the effective transconductance (Gm) of the transconductance stage 402 while not reducing the output impedances. This increases the DC gain, which is the product of Gm and Rout. There is also an increase in the unity gain bandwidth (UGBW), which is directly proportional to Gm for a given load capacitor and feedback factor. Thus, if the current gain is K, the effective Gm for the example shown in FIG. 5 can be expressed as [(Gm/2)+K*(Gm/2)].

It should also be noted that the transistor devices shown in FIG. 5 include associated size designators (X, Y, Z, and Zn) that indicate the relative size of the devices, which also relates to the transconductance of the devices. Due to the telescopic architecture of the OTA 500, the impedance (Rup) can be expressed as [(Gm_{(x/2)}/2)*(2*rₒₓ)*(2*r_{oz})] and the impedance (Rdown) can be expressed as [(Gm_{(y/2)}/2)*(2r_{oy})*(r_{ozn})]. Thus, it can be simply stated that (Rup=Rup1=Rup2) and (Rdown=Rdown1=Rdown2). For high values of K, the improvement can be significant. In an exemplary embodiment, setting K to a value of 2 achieves better performance with 25% less current consumption. In an exemplary embodiment, with a tight phase margin requirement, a relatively less aggressive value of K can be chosen and when lower phase margins can be tolerated, a higher value of K can be chosen. In the above equations, Gm(x/2) is the transconductance of the upper cascode devices (e.g., transistors 524 and 532), rox is the output impedance of the upper cascode devices, roz is the output impedance of the input devices (e.g., transistors 522 and 530), Gm(y/2) is the transconductance of the lower cascode device (e.g., transistor 554), roy is the output impedance of the lower cascode device, and rozn is the output impedance of the active load device (e.g., transistor 538).

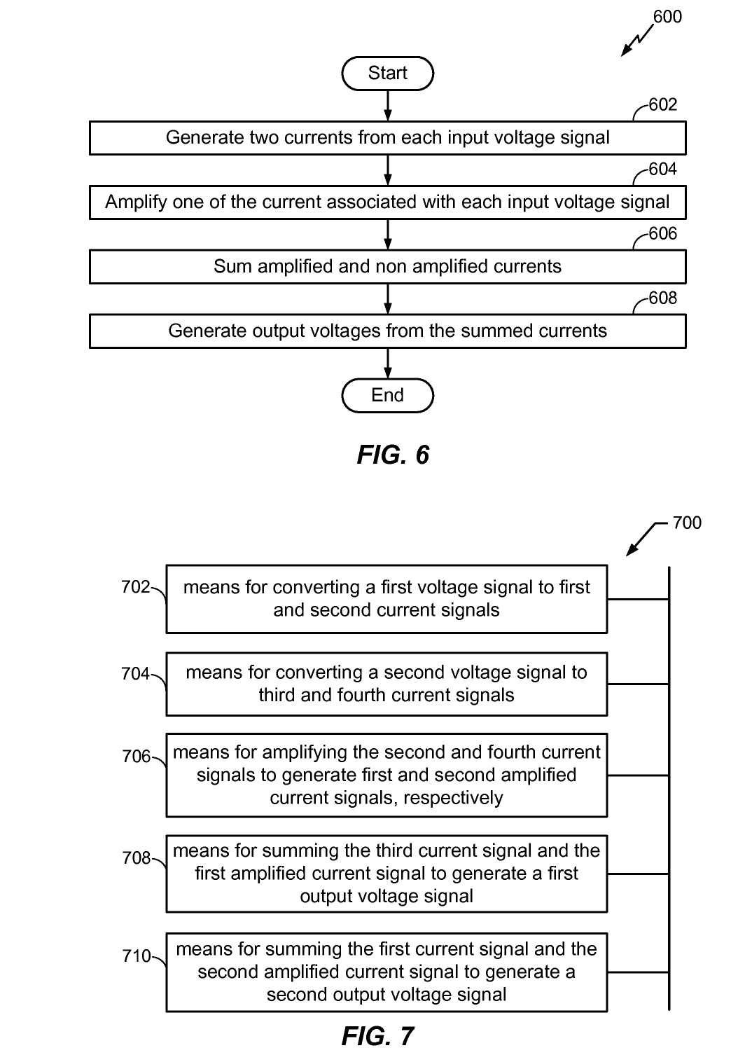

FIG. 6 shows exemplary operations performed by an exemplary embodiment of the operational transconductance amplifier 500. For example, in an exemplary embodiment, the OTA 500 performs the operations 600 to amplify differential input voltages in a device, such as the wireless device 110 shown in FIG. 1.

During operation 602, currents are generated from differential input voltage signals. For example, the Gm circuits 408, 410, 412, and 414 generate the currents 422, 416, 430, and 424 from the first input voltage Vi₁ and the second input voltage Vi₂. In an exemplary embodiment, the Gm circuits 408 and 412 have the same transconductance values and the Gm circuits 410 and 414 have the same transconductance values, which may also be equal to the Gm circuits 408 and 412.

During operation 604, one current associated with each input voltage signal is amplified. For example, the current amplifier 418 amplifies the current 416 to generate the first amplified current 420. The current amplifier 426 amplifies the current 424 to generate the second amplified current 428.

During operation 606, the amplified and non-amplified currents are selectively summed together. For example, the first summing circuit 552 sums the current 420 and the current 430 and the second summing circuit 558 sums the current 428 and the current 422.

During operation 608, output voltages are generated from the summed currents.

For example, the first summing circuit 552 generates the output voltage Vo1 at node 432 based on its summed current and the output impedance (Rout1) and the second summing circuit 558 generates the output voltage Vo2 at the node 436 based on its summed current and the output impedance (Rout2).

Accordingly, the OTA 500 performs the operations described above to amplify differential voltages in a device to provide improved DC gain and unity gain bandwidth over conventional amplifier circuits. It should be noted that the operations 600 are exemplary and that minor changes, modifications, rearrangements and other changes to the operations 600 are within the scope of the exemplary embodiments.

FIG. 7 shows an exemplary embodiment of an operational transconductance amplifier apparatus 700. In an exemplary embodiment, the apparatus 700 is suitable for use as the OTA 500 shown in FIG. 5.

The apparatus 700 includes a first means (702) for converting a first voltage signal to first and second current signals, which in an exemplary embodiment comprises the first 408 and second 410 Gm circuits. The apparatus 700 also comprises a second means (704) for converting a second voltage signal to third and fourth current signals, which in an exemplary embodiment comprises the third 412 and fourth 414 Gm circuits. The apparatus 700 also comprises a third means (706) for amplifying the second and fourth current signals to generate first and second amplified current signals, respectively, which in an exemplary embodiment comprises the first 418 and second 426 current amplifiers. The apparatus 700 also comprises a fourth means (708) for summing the third current signal and the first amplified current signal to generate a first output voltage signal, which in an exemplary embodiment comprises the first summing circuit 552. The apparatus 700 also comprises a fifth means (710) for summing the first current signal and the second amplified current signal to generate a second output voltage signal, which in an exemplary embodiment comprises the second summing circuit 558.

The exemplary embodiments of an OTA described herein may be implemented on an IC, an analog IC, an RFIC, a mixed-signal IC, an ASIC, a printed circuit board (PCB), an electronic device, etc. The exemplary embodiments of the OTA may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

An apparatus implementing an exemplary embodiment of an OTA described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

The previous description of the disclosure is provided to enable any person skilled in the art to make or use the disclosure. Various modifications to the disclosure will be readily apparent to those skilled in the art, and the generic principles defined herein may be applied to other variations without departing from the scope of the disclosure. Thus, the disclosure is not intended to be limited to the examples and designs described herein but the disclose is to be accorded the widest scope consistent with the principles and novel features disclosed herein.

What is claimed is:

1. An apparatus comprising:
a transconductance stage configured to convert a first input voltage signal to first and second current signals and to convert a second input voltage signal to third and fourth current signals;
a current amplification stage configured to amplify the second current signal to generate a first amplified current signal and to amplify the fourth current signal to generate a second amplified current signal; and
a current summation stage configured to sum together the third current signal and the first amplified current signal to generate a first output voltage signal, and to sum together the first current signal and the second amplified current signal to generate a second output voltage signal.

2. The apparatus of claim 1, the transconductance stage comprising:
first and second transconductance circuits configured to convert the first voltage signal to the first and second current signals; and
third and fourth transconductance circuits configured to convert the second voltage signal to the third and fourth current signals.

3. The apparatus of claim 2, the first and third transconductance circuits have substantially the same transconductance values, and the second and fourth transconductance circuits have substantially the same transconductance values.

4. The apparatus of claim 2, the first transconductance circuit including a first cascode transistor pair configured to receive the first input voltage and generate the first current signal, the second transconductance circuit including a second cascode transistor pair configured to receive the first input voltage and generate the second current signal, the third transconductance circuit including a third cascode transistor pair configured to receive the second input voltage and generate the third current signal, the fourth transconductance circuit including a fourth cascode transistor pair configured to receive the second input voltage and generate the fourth current signal,

5. The apparatus of claim 1, the current amplification stage comprising:
a first current amplifier configured to amplify the second current signal by a first amplification factor to generate the first amplified current signal; and
a second current amplifier configured to amplify the fourth current signal by a second amplification factor to generate the second amplified current signal.

6. The apparatus of claim 5, the first amplification factor is substantially the same as the second amplification factor.

7. The apparatus of claim 5, the first current amplifier including a first common source transistor having a drain terminal configured to receive the second current signal and a second common source transistor having a drain terminal configured to output the first amplified current signal and the second current amplifier including a third common source transistor having a drain terminal configured to receive the fourth current signal and a fourth common source transistor having a drain terminal configured to output the second amplified current signal.

8. The apparatus of claim 1, the current summation stage comprising:
a first summing circuit configured to sum together the third current signal and the first amplified current signal to form a first summed current and to convert the first summed current to the first output voltage signal based on a first impedance; and
a second summing circuit configured to sum together the first current signal and the second amplified current signal to form a second summed current and to convert the second summed current to the second output voltage signal based on a second impedance.

9. The apparatus of claim 8, the first summing circuit including a first transistor having a drain terminal configured to receives the third current signal and a source terminal configured to receive the first amplified current signal to generate the first summed current, and the second summing circuit including a second transistor having a drain terminal configured to receive the first current signal and a source terminal configured to receive the second amplified current signal to generate the second summed current.

10. The apparatus of claim 1, the apparatus forming an operational transconductance amplifier.

11. The apparatus of claim 1, the first and second input voltage signals form a differential input signal and the first and second output voltage signals form a differential output signal.

12. An apparatus comprising:
means for converting a first voltage signal to first and second current signals;
means for converting a second voltage signal to third and fourth current signals;
means for amplifying the second and fourth current signals to generate first and second amplified current signals, respectively;
means for summing the third current signal and the first amplified current signal to generate a first output voltage signal; and
means for summing the first current signal and the second amplified current signal to generate a second output voltage signal.

13. The apparatus of claim 12, the means for converting the first voltage signal comprising first and second transconductance circuits and the means for converting the second voltage signal comprising third and fourth transconductance circuits.

14. The apparatus of claim 13, the first and third transconductance circuits having substantially the same transconductance values, and the second and fourth transconductance circuits having substantially the same transconductance values.

15. The apparatus of claim 11, the means for amplifying amplifies the second current signal by an first amplification factor to generate the first amplified current signal and amplifies the fourth current signal by a second amplification factor to generate the second amplified current signal.

16. The apparatus of claim 15, the first amplification factor is substantially the same as the second amplification factor.

17. The apparatus of claim 11, the apparatus forming an operational transconductance amplifier.

18. The apparatus of claim 11, the first and second input voltage signals form a differential input signal and the first and second output voltage signals form a differential output signal.

19. A method comprising:
converting a first voltage signal to first and second current signals;
converting a second voltage signal to third and fourth current signals;
amplifying the second and fourth current signals to generate first and second amplified current signals, respectively;
summing the third current signal and the first amplified current signal to generate a first output voltage signal; and
summing the first current signal and the second amplified current signal to generate a second output voltage signal.

20. The method of claim 19, the first and second input voltage signals form a differential input signal and the first and second output voltage signals form a differential output signal.
